(19) United States
(12) Patent Application Publication
(10) Pub. No.: US 2025/0022983 A1
(43) Pub. Date: Jan. 16, 2025

(54) CURRENT INJECTION STRUCTURES FOR LIGHT-EMITTING DIODE CHIPS

(71) Applicant: CreeLED, Inc., Durham, NC (US)

(72) Inventors: Michael Check, Holly Springs, NC (US); David Suich, Durham, NC (US); Thomas Celano, Cary, NC (US); Joseph G. Sokol, Durham, NC (US); Colin Blakely, Raleigh, NC (US)

(21) Appl. No.: 18/221,474

(22) Filed: Jul. 13, 2023

(51) Int. Cl. H01L 33/14; H01L 33/10; H01L 33/40

(52) U.S. Cl. CPC H01L 33/14; H01L 33/10; H01L 33/40

(57) ABSTRACT

Solid-state lighting devices including light-emitting diodes (LEDs) and more particularly current injection structures for LED chips are disclosed. Current injection structures include integrated layers or materials with high work functions as part of contact structures for epitaxial layers of active LED structures. Exemplary structures provide high work function contact layers for p-type epitaxial layers to enhance hole mobility and transport. Further contact structures include combinations of high work function layers with other current spreading layers. Exemplary materials for high work function layers include transition metal oxides.

### FIELD OF THE DISCLOSURE

The present disclosure relates to solid-state lighting devices including light-emitting diodes (LEDs) and more particularly to current injection structures for LED chips.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by how well current is able to spread within an LED. To increase current spreading for LEDs, and in particular for larger area LEDs, it has been found useful to add layers of high electrical conductivity over one or more epitaxial layers of an LED. Electrodes for the LEDs can have larger surface areas and may include various electrode extensions or fingers that are configured to route and more evenly distribute current across an LED.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to current injection structures for LED chips. Current injection structures include integrated layers or materials with high work functions as part of contact structures for epitaxial layers of active LED structures. Exemplary structures provide high work function contact layers for p-type epitaxial layers to enhance hole mobility and transport. Further contact structures include combinations of high work function layers with other current spreading layers. Exemplary materials for high work function layers include transition metal oxides.

In one aspect, an LED chip comprises: an active LED structure comprising an n-type layer, a p-type layer, and an active layer between the n-type layer and the p-type layer; a current spreading layer on the p-type layer; and a contact layer between the current spreading layer and the p-type layer, the contact layer comprising a transition metal oxide. In certain embodiments, the transition metal oxide comprises molybdenum oxide. In certain embodiments, the transition metal oxide comprises at least one of tungsten oxide and vanadium oxide. In certain embodiments, the transition metal oxide comprises molybdenum oxide and the current spreading layer comprises indium tin oxide. In certain embodiments, the contact layer comprises a work function in a range from 6 electron volts (eV) to 10 eV. In certain embodiments, the contact layer comprises a thickness in a range from 1 nanometer (nm) to 100 nm. The LED chip may further comprise: a dielectric reflector layer on the p-type layer; a metal reflector layer on the dielectric reflector layer; and a plurality of reflective layer interconnects that extend through the dielectric reflector layer to form a plurality of electrically conductive paths between the metal reflector layer and the current spreading layer. In certain embodiments, the plurality of electrically conductive paths comprises a portion of the contact layer between the p-type layer and each reflective layer interconnect of the plurality of reflective layer interconnects. In certain embodiments, the contact layer comprises a first sublayer and a second sublayer with different work functions. In certain embodiments: the first sublayer has a higher work function than the second sublayer; and the first sublayer is closer to the p-type layer than the second sublayer.

In another aspect, an LED chip comprises: an active LED structure comprising an n-type layer, a p-type layer, and an active layer between the n-type layer and the p-type layer; a current spreading layer on the p-type layer; and a contact layer between the current spreading layer and the p-type layer, the contact layer comprising a work function that is in a range from 6 electron volts (eV) to 10 eV. In certain embodiments, the contact layer comprises at least one of molybdenum oxide, tungsten oxide, and vanadium oxide. In certain embodiments, the contact layer comprises molybdenum oxide and the current spreading layer comprises indium tin oxide. The LED chip may further comprise: a dielectric reflector layer on the current spreading layer; a metal reflector layer on the dielectric reflector layer; and a plurality of reflective layer interconnects that extend through the dielectric reflector layer to form a plurality of electrically conductive paths between the metal reflector layer and a plurality of discontinuous regions of the current spreading layer.

In another aspect, an LED chip comprises: an active LED structure comprising an n-type layer, a p-type layer, and an active layer between the n-type layer and the p-type layer; a current spreading layer forming a plurality of discontinuous current spreading layer regions on the p-type layer; and a contact layer between the current spreading layer and the p-type layer. In certain embodiments, the contact layer forms a plurality of discontinuous contact layer regions. In certain embodiments, the contact layer comprises a transition metal oxide. In certain embodiments, the transition metal oxide comprises at least one of molybdenum oxide, tungsten oxide and vanadium oxide. In certain embodiments, the contact layer comprises a work function in a range from 6electron volts (eV) to 10 eV. The LED chip may further comprise: a dielectric reflector layer on the current spreading layer; a metal reflector layer on the dielectric reflector layer; and a plurality of reflective layer interconnects that extend through the dielectric reflector layer to form a plurality of electrically conductive paths between the metal reflector layer and the plurality of discontinuous current spreading layer regions.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of an exemplary light-emitting diode (LED) chip with a contact layer having a high work function according to principles of the present disclosure.

FIG. 1B is a cross-sectional view of a portion of the LED chip of FIG. 1A.

FIG. 2 is a cross-sectional view of a portion of an LED chip that is similar to the LED chip of FIGS. 1A and 1B and is without the current spreading layer of FIG. 1B.

FIG. 3 is a cross-sectional view of a portion of an LED chip that is similar to the LED chip of FIG. 2 for embodiments where the p-type layer does not include a sublayer with higher p-type doping levels at a top surface of the p-type layer.

FIG. 4 is a cross-sectional view of a portion of an LED chip that is similar to the LED chip of FIGS. 1A and 1B for embodiments where the current spreading layer is discontinuous over portions of the contact layer.

FIG. 5 is a cross-sectional view of a portion of an LED chip that is similar to the LED chip of FIG. 4 except the contact layer forms a plurality of discontinuous contact layer regions.

FIG. 6 is a cross-sectional view of a portion of an LED chip that is similar to the LED chip of FIGS. 1A and 1B for embodiments where the contact layer includes a plurality of sublayers.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to current injection structures for LED chips. Current injection structures include integrated layers or materials with high work functions as part of contact structures for epitaxial layers of active LED structures. Exemplary structures provide high work function contact layers for p-type epitaxial layers to enhance hole mobility and transport. Further contact structures include combinations of high work function layers with other current spreading layers. Exemplary materials for high work function layers include transition metal oxides.

An LED chip typically comprises an active LED structure or region that can have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface.

The present disclosure may be useful for LED chips with current spreading structures that distribute current across active LED structure areas. Current spreading structures may include various contacts, interconnects, and electrically conductive layers that effectively route current across an LED chip for reduced current crowding. N-contact interconnect structures may include electrically conductive materials that contact an n-type layer of the active LED structure. Various LED chips, including large area LED chips, typically include a plurality of n-contact interconnects that are distributed across an area of the active LED structure. The n-contact interconnects provide multiple electrical connection points to the n-type layer, and the n-contact interconnects may be connected to one or more n-contacts of the LED chip. P-contact interconnect structures also include electrically conductive materials connected to a p-type layer of the active LED structure.

In typical LED structures, such as GaN-based material systems, hole mobility is usually lower than electron mobility. In this regard, challenges exist for providing suitable contact structures for p-type layers. In the example of GaN-based material systems, p-type epitaxial layers are typically doped with Mg; however, there are practical limits for Mg doping levels. While increased Mg doping generally corresponds with increased hole mobility, if Mg levels become too high, the p-type layers can become more absorbing to light, thereby contributing to light extraction loss. In this manner, trade-offs exist between hole mobility and light-transmissive properties of p-type layers. Current spreading layers, such as indium tin oxide (ITO), may be used between metal contact layers and p-type layers to enhance hole transport and injection.

According to aspects of the present disclosure, further current injection improvements are provided with structures that include high work function layers as part of contact structures. For example, hole transport and/or injection may be increased by placement of a high work function layer or material on the p-type layer. In certain embodiments, the high work function layer may be positioned with another current spreading layer, such as ITO, to provide further mobility improvements. For example, the high work function layer may be provided on or directly on a surface of the p-type layer and between the other current spreading layers and the p-type layer. Deep-lying electronic states and high work functions of such layers or materials provide reduced energy barriers for hole transfer and may also serve as hole selective transport layers and/electron blocking layers. Additionally, the ionization energy of such layers may provide defect states that serve as electron acceptors, which may lead to beneficial band bending in contact structures.

As used herein, a high work function layer or material refers to a work function of greater than 6 electron volts (eV) as measured from a material's vacuum level to its fermi level. In certain embodiments, the high work function layer may have a work function greater than 6 eV, or greater than 6.5 eV, or in a range from 6 eV to 10 eV, or in a range from 6.5 eV to 10 eV. In certain embodiments, the high work function layer comprises a transition metal oxide, such as molybdenum oxide (MoO₃), tungsten oxide (WO₃), and vanadium oxide (V₂Oₓ). According to aspects of the present disclosure, high work function layers may also be transparent to visible wavelengths for increased light emission efficiency.

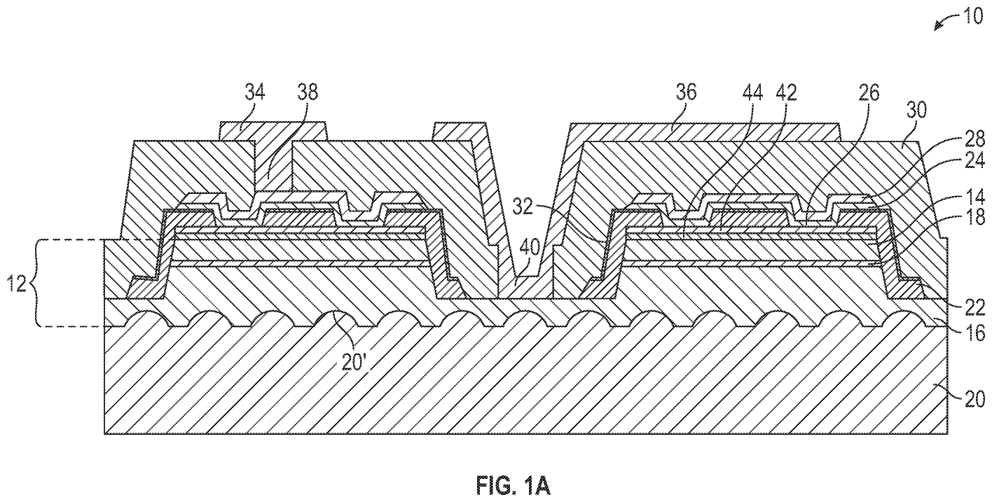

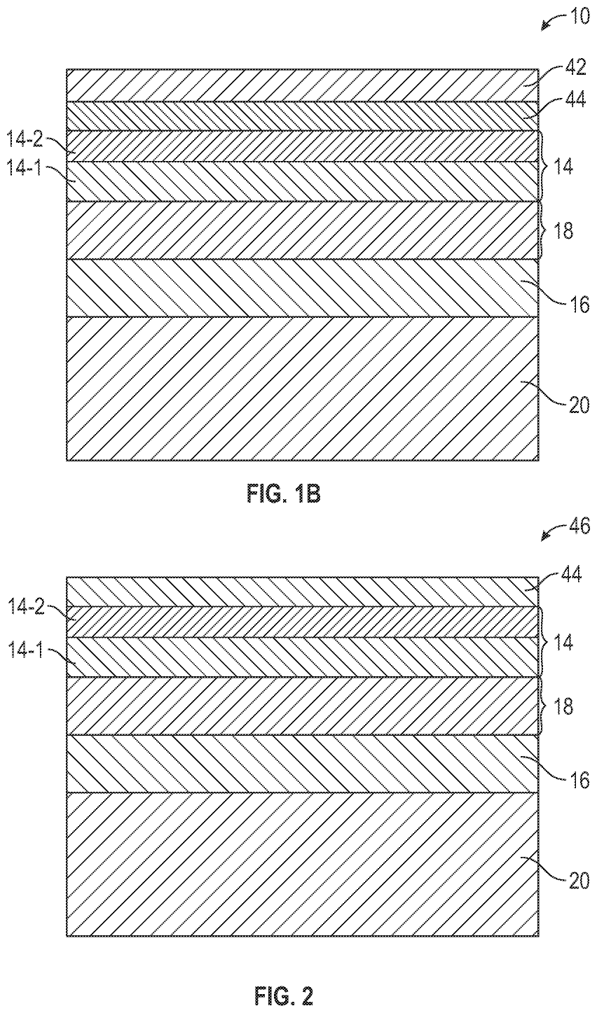

FIG. 1A is a cross-sectional view of an exemplary LED chip 10 according to principles of the present disclosure. The LED chip 10 includes an active LED structure 12 comprising a p-type layer 14, an n-type layer 16, and an active layer 18 therebetween. The active LED structure 12 may be formed on a substrate 20. In certain embodiments, one or more buffer layers and/or undoped layers may be provided between the substrate 20 and n-type layer 16 of the active LED structure 12. In certain embodiments, the n-type layer 16 is between the active layer 18 and the substrate 20. In other embodiments, the doping order may be reversed. The substrate 20 can comprise many different materials such as SiC or sapphire and can have one or more surfaces that are shaped, textured, or patterned to enhance light extraction. In certain embodiments, the substrate 20 is light transmissive (preferably transparent) and may include a patterned surface 20′ that is proximate the active LED structure 12 and includes multiple recessed and/or raised features.

In FIG. 1A, a first reflective layer 22 is provided on portions of the p-type layer 14. The first reflective layer 22 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the first reflective layer 22 comprises a material with an index of refraction lower than the index of refraction of the active LED structure 12 material. The first reflective layer 22 may comprise many different materials, with some having an index of refraction less than 2.3, while others can have an index of refraction less than 2.15, less than 2.0, and less than 1.5. In some embodiments, the first reflective layer 22 comprises a dielectric material, with some embodiments comprising silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. Accordingly, the first reflective layer 22 may be referred to as a dielectric reflector layer and/or a dielectric reflective layer. In certain embodiments, the first reflective layer 22 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the first reflective layer 22 comprising SiO₂ can have a sufficient index of refraction step between the two to allow for efficient TIR of light. The first reflective layer 22 can have different thicknesses depending on the type of materials used, with some embodiments having a thickness of at least 0.2 microns (μm). In some of these embodiments, the first reflective layer 22 can have a thickness in the range of 0.2 μm to 0.7 μm, while in some of these embodiments the thickness can be approximately 0.5 μm. Portions of the first reflective layer 22 may extend along mesa sidewalls of the active LED structure 12 and along sidewall portions of the p-type layer 14, the active layer 18, and the n-type layer 16.

The LED chip 10 may further include a second reflective layer 24 that is on the first reflective layer 22 such that the first reflective layer 22 is arranged between the active LED structure 12 and the second reflective layer 24. The second reflective layer 24 may include a metal layer that is configured to reflect any light from the active LED structure 12 that may pass through the first reflective layer 22. The second reflective layer 24 can comprise many different materials such as Ag, gold (Au), or combinations thereof. Accordingly, the second reflective layer 24 may be referred to as a metal reflector layer and/or a metal reflective layer. As illustrated, the second reflective layer 24 may include one or more reflective layer interconnects 26 that provide electrically conductive paths through the first reflective layer 22 to the p-type layer 14. In certain embodiments, the reflective layer interconnects 26 comprise reflective layer vias. Accordingly, the first reflective layer 22, the second reflective layer 24, and the reflective layer interconnects 26 form a reflective structure of the LED chip 10. In some embodiments, the reflective layer interconnects 26 comprise the same material as the second reflective layer 24 and are formed at the same time as the second reflective layer 24. In other embodiments, the reflective layer interconnects 26 may comprise a different material than the second reflective layer 24.

The LED chip 10 may also comprise a barrier layer 28 on a side of the second reflective layer 24 opposite the first reflective layer 22 to prevent migration of the second reflective layer 24 material, such as Ag, to other layers. Preventing this migration helps the LED chip 10 maintain efficient operation through its lifetime. The barrier layer 28 may comprise an electrically conductive material, with suitable materials including but not limited to sputtered Ti/Pt followed by evaporated Au bulk material or sputtered Ti/Ni followed by an evaporated Ti/Au bulk material.

A passivation layer 30 may be included on the barrier layer 28 as well as any portions of the second reflective layer 24 that may be uncovered by the barrier layer 28. The passivation layer 30 may further be arranged on portions of the first reflective layer 22 that are uncovered by the second reflective layer 24. The passivation layer 30 protects and provides electrical insulation for the LED chip 10 and can comprise many different materials, such as a dielectric material. In certain embodiments, the passivation layer 30 is a single layer, and in other embodiments, the passivation layer 30 comprises a plurality of layers. A suitable material for the passivation layer 30 includes but is not limited to SIN, SiNx, and/or Si₃N₄. In certain embodiments, the first reflective layer 22 comprises SiO₂ and the passivation layer 30 comprises SiN, SiNx, or Si₃N₄. In other embodiments, the first reflective layer 22 and at least a portion of the passivation layer 30 may each comprise SiO₂. As illustrated, the first reflective layer 22 may bound perimeter and/or sidewall portions of the active LED structure 12, including the p-type layer 14, the active layer 18, and the n-type layer 16, along a perimeter of the LED chip 10. Furthermore, the passivation layer 30 may be arranged to also bound perimeter portions of the active LED structure 12. In this manner, portions of the first reflective layer 22 may be arranged between portions of the passivation layer 30 along sidewalls of active LED structure 12 for enhanced passivation and protection.

Certain embodiments may also comprise one or more adhesion layers 32 positioned at one or more interfaces between the first reflective layer 22 and the second reflective layer 24 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlxOy. In certain embodiments, the adhesion layer 32 comprises AlₓO_{y}, where 1≤x≤4 and 1≤y≤6. In certain embodiments, the adhesion layer 32 comprises AlₓO_{y}, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD).

In FIG. 1A, the LED chip 10 comprises a p-contact 34 and an n-contact 36 that are arranged on the passivation layer 30 and are configured to provide electrical connections with the active LED structure 12. The p-contact 34, which may also be referred to as an anode contact, may comprise one or more p-contact interconnects 38 that extend through the passivation layer 30 to the barrier layer 28 or the second reflective layer 24 to provide an electrical path to the p-type layer 14. In certain embodiments, the one or more p-contact interconnects 38 comprise one or more p-contact vias. The n-contact 36, which may also be referred to as a cathode contact, is electrically coupled to the n-type layer 16 by way of one or more n-contact interconnects 40 that extend through the passivation layer 30, the barrier layer 28, the first and second reflective layers 22, 24, the p-type layer 14, and the active layer 18. In certain embodiments, the one or more n-contact interconnects 40 may be referred to as one or more n-contact vias. Openings for the n-contact interconnects 40 may be formed in a separate etching step than etching along the perimeter of the LED chip 10 where the passivation layer 30 bounds the active LED structure 12. For illustrative purposes, FIG. 1A is shown with a single n-contact interconnect 40. In practice, the LED chip 10 may include multiple n-contact interconnects 40 spaced apart in an array pattern across the active LED structure 12.

In operation, a signal applied across the p-contact 34 and the n-contact 36 is conducted to the p-type layer 14 and the n-type layer 16, causing the LED chip 10 to emit light from the active layer 18. The p-contact 34 and the n-contact 36 can comprise many different materials such as Au, copper (Cu), nickel (Ni), In, Al, Ag, tin (Sn), Pt, or combinations thereof. In still other embodiments, the p-contact 34 and the n-contact 36 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. In certain embodiments, the LED chip 10 is arranged for flip-chip mounting and the p-contact 34 and n-contact 36 are configured to be mounted or bonded to a surface, such as a printed circuit board. While FIG. 1A is described in the context of a flip-chip structure, the principles disclosed are readily applicable to other chip structures.

The electrically conductive path from the p-contact 34 to the p-type layer 14 may further include a current spreading layer 42 and a contact layer 44 with a high work function between the current spreading layer 42 and the p-type layer 14. The current spreading layer 42 may embody a layer of conductive material, for example a transparent conductive oxide such as indium tin oxide (ITO) or a metal such as platinum (Pt), although other materials may be used. In certain embodiments, the current spreading layer 42 is formed with a number of openings or even discontinuous regions on the p-type layer 14. In such arrangements, portions of the first reflective layer 22 may extend through the current spreading layer 26 and contact the p-type layer 14 and provide increased light reflectivity. In other arrangements, the current spreading layer 26 could continuously cover the p-type layer 14.

In certain applications, the current spreading layer 42 may be become more light absorbing with increased thickness, thereby providing practical limitations. By positioning the contact layer 44 with high work function between the current spreading layer 42 and the p-type layer 14, an enhanced current injection structure may be provided. In this manner, the LED chip 10 may exhibit increased hole transport and/or injection at the p-type layer 14 while also maintaining current spreading improvements provided by the current spreading layer 42. Additionally, the current spreading layer 42 may promote enhanced adhesion with the second reflective layer 24 at the reflective layer interconnects 26, rather than if the second reflective layer 24 contacted the contact layer 44 at the reflective layer interconnects 26. In this manner, the structural integrity of the electrically conductive path to the p-type layer 14 may be maintained.

As described above, the contact layer 44 with high work function may comprise a transition metal oxide, such as molybdenum oxide (MoO₃), tungsten oxide (WO₃), and vanadium oxide (V₂Oₓ). In certain embodiments, the work function of the contact layer 44 is greater than 6 eV, or greater than 6.5 eV, or in a range from 6 eV to 10 eV, or in a range from 6.5 eV to 10 eV. In contrast, the current spreading layer 42 may have a work function that is 5 eV or less. In certain embodiments, a thickness of the contact layer 44 is in a range from 1 nm to 100 nm, or in a range from 1 nm to 50 nm, or in a range from 2 nm to 10 nm. If the contact layer 44 is too thick, the contact layer could exhibit increased light absorption and/or a Schottky contact could form rather than the desired ohmic contact. Additionally, thinner layers, such as the ranges provided above, may provide defects of the contact layer 44 as surface defects that may further enhance current spreading. Within these thickness ranges, particularly the lower values, it is also possible that the contact layer 44 does not continuously cover the p-type layer 14. In such embodiments, portions of the current spreading layer 42 may fill gaps formed by discontinuous portions of the contact layer 44. FIG. 1B is a cross-sectional view of a portion of the LED chip 10 of

FIG. 1A. In certain embodiments, the p-type layer 14 may comprise a multiple layer structure. For example, the p-type layer 14 may include a first sublayer 14-1 and a second sublayer 14-2. The first sublayer 14-1 is arranged closer to the active layer 18 than the second sublayer 14-2. In certain embodiments, the second sublayer 14-2 may have increased p-type doping levels as compared to the first sublayer 14-1. Such a structure may provide certain advantages of increased hole mobility in the p-type layer 14 without having the higher p-type doping levels through the entire p-type layer 14 to avoid light absorption. While a two-layer structure is illustrated, the p-type layer 14 may have any number of sublayers with varying p-type doping levels that seek to balance trade-offs between hole mobility and light absorption. As illustrated, the contact layer 44 is between the current spreading layer 42 and the p-type layer 14 or second sublayer 14-2.

FIG. 2 is a cross-sectional view of a portion of an LED chip 46 that is similar to the LED chip 10 of FIGS. 1A and 1B and is without the current spreading layer 42 of FIG. 1B. In this regard, the contact layer 44 may provide sufficient current injection for the p-type layer 14 for areas of the LED chip 46 where the current spreading layer is not present. In certain embodiments, the entire LED chip 46 may be devoid of the current spreading layer 42 of FIG. 1B. In other embodiments, the current spreading layer 42 of FIG. 1B may be discontinuous and FIG. 2 represents such portions of the LED chip 46.

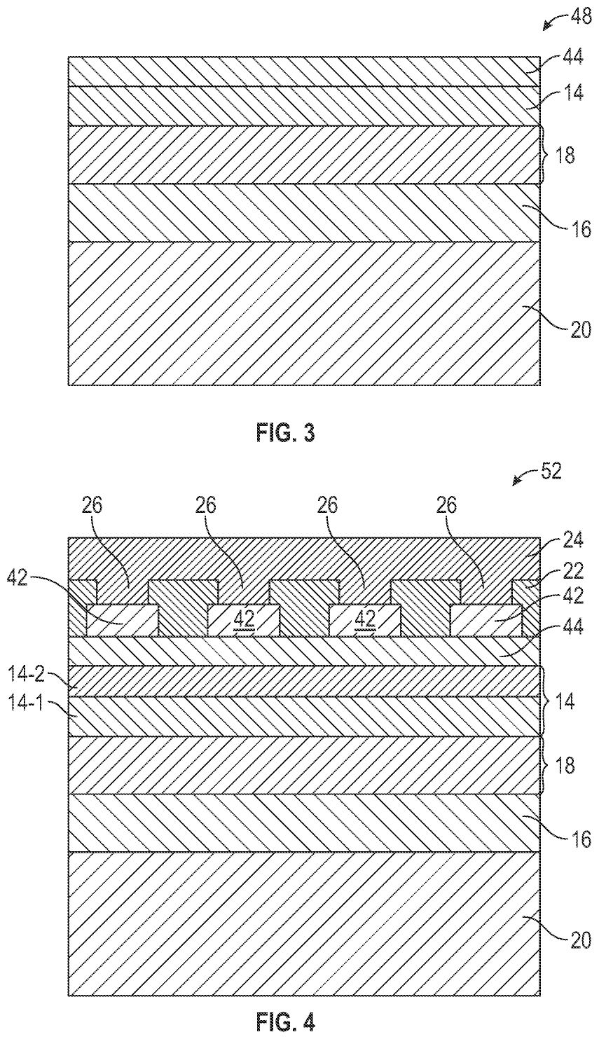

FIG. 3 is a cross-sectional view of a portion of an LED chip 48 that is similar to the LED chip 46 of FIG. 2 for embodiments where the p-type layer 14 does not include a sublayer with higher p-type doping levels at a top surface of the p-type layer 14. In certain embodiments, the contact layer 44 may provide sufficient current injection for the p-type layer 18. Accordingly, the p-type layer 14 may be formed with suitable p-type doping levels to maintain p-type conductivity without having higher doping regions that could increase light absorption and/or reduce crystal quality.

FIG. 4 is a cross-sectional view of a portion of an LED chip 52 that is similar to the LED chip 10 of FIGS. 1A and 1B for embodiments where the current spreading layer 42 is discontinuous over portions of the contact layer 44. In this manner, portions of the first reflective layer 22 may be directly on portions of the contact layer 44 that are between discontinuous regions of the current spreading layer 42. In this regard, absorption losses associated with the material of the current spreading layer 42 may be reduced. Additionally, the first reflective layer 22 is formed with increased surface area and portions thereof may be positioned closer to the p-type layer 14 for increased reflectivity and/or improved light scattering. As illustrated, the reflective layer interconnects 26 may extend through the first reflective layer 22 to contact the discontinuous regions of the current spreading layer 42. In certain embodiments, each reflective layer interconnect 26 electrically contacts a different discontinuous region of the current spreading layer 42. In other embodiments, multiple reflective layer interconnects 26 may contact a same discontinuous region of the current spreading layer 42.

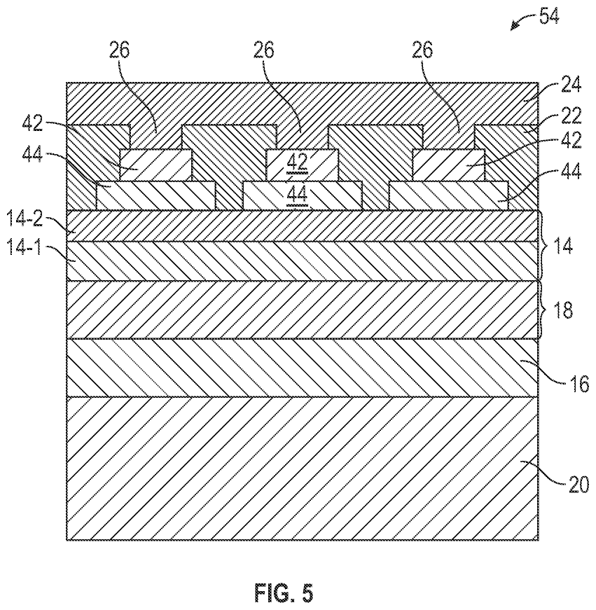

FIG. 5 is a cross-sectional view of a portion of an LED chip 54 that is similar to the LED chip 52 of FIG. 4 except the contact layer 44 forms a plurality of discontinuous contact layer regions. In this manner, both the current spreading layer 42 and the contact layer 44 are formed with discontinuous regions across the p-type layer 14. As illustrated, portions of the first reflective layer 22 may contact the p-type layer 14 between these discontinuous regions for reduced absorption, increased reflectivity, and/or increased light scattering. In certain embodiments, electrically conductive paths between the second reflective layer 24 and the p-type layer 14 include at least one discontinuous region of the current spreading layer 42 and at least one discontinuous region of the contact layer 44.

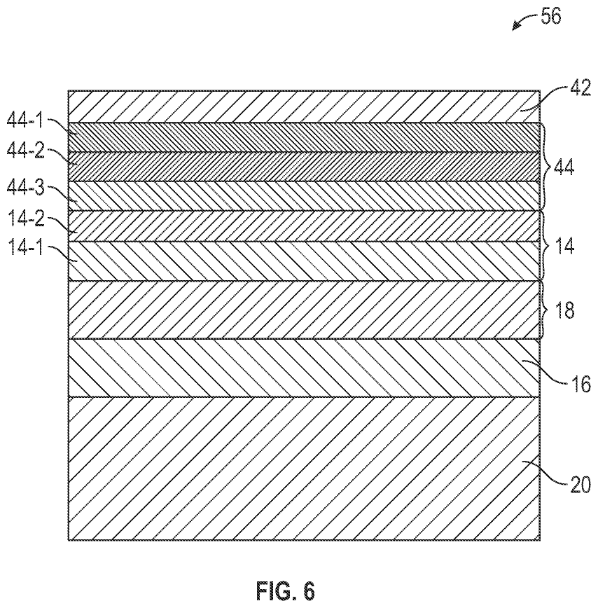

FIG. 6 is a cross-sectional view of a portion of an LED chip 56 that is similar to the LED chip 10 of FIGS. 1A and 1B for embodiments where the contact layer 44 includes a plurality of sublayers 44-1 to 44-3. By subdividing the contact layer 44 into the sublayers 44-1 to 44-3, band bending and/or work functions within the contact layer 44 may be tailored for different current injection structures based on energy alignment for controlling injection barriers and transport. For example, different types of junctions may include straddling contacts for hetero-contact layers or staggered contacts (e.g., stair-stepped profiles). In FIG. 6, work functions may be different in ones of the sublayers 44-1 to 44-3. For example, the work functions may be graded from high to low in a direction from the p-type layer 14 or p-type sublayer 14-2. In this regard, the sublayer 44-3 may have the highest work function within the contact layer 44. In certain embodiments, the work function may progressively decrease with each sublayer 44-2, 44-3 in a direction away from the p-type layer 14. The work functions may be varied within the sublayers 44-1 to 44-3 by having different material types, such as different combinations of molybdenum oxide, tungsten oxide and vanadium oxide. The work functions may also be varied by introducing surface defects and/or oxygen vacancies in certain sublayers 44-1 to 44-3, and/or by varying molybdenum oxygen stoichiometries. While FIG. 6 is illustrated with three sublayers 44-1 to 44-3, the contact layer 44 may have any number of sublayers from two total to more than three without deviating from the principles disclosed.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
an active LED structure comprising an n-type layer, a p-type layer, and an active layer between the n-type layer and the p-type layer;
a current spreading layer on the p-type layer; and
a contact layer between the current spreading layer and the p-type layer, the contact layer comprising a transition metal oxide.

2. The LED chip of claim 1, wherein the transition metal oxide comprises molybdenum oxide.

3. The LED chip of claim 1, wherein the transition metal oxide comprises at least one of tungsten oxide and vanadium oxide.

4. The LED chip of claim 1, wherein the transition metal oxide comprises molybdenum oxide and the current spreading layer comprises indium tin oxide.

5. The LED chip of claim 1, wherein the contact layer comprises a work function in a range from 6 electron volts (eV) to 10 eV.

6. The LED chip of claim 1, wherein the contact layer comprises a thickness in a range from 1 nanometer (nm) to 100 nm.

7. The LED chip of claim 1, further comprising:
a dielectric reflector layer on the p-type layer;
a metal reflector layer on the dielectric reflector layer; and
a plurality of reflective layer interconnects that extend through the dielectric reflector layer to form a plurality of electrically conductive paths between the metal reflector layer and the current spreading layer.

8. The LED chip of claim 7, wherein the plurality of electrically conductive paths comprises a portion of the contact layer between the p-type layer and each reflective layer interconnect of the plurality of reflective layer interconnects.

9. The LED chip of claim 1, wherein the contact layer comprises a first sublayer and a second sublayer with different work functions.

10. The LED chip of claim 9, wherein:
the first sublayer has a higher work function than the second sublayer; and
the first sublayer is closer to the p-type layer than the second sublayer.

11. A light-emitting diode (LED) chip comprising:
an active LED structure comprising an n-type layer, a p-type layer, and an active layer between the n-type layer and the p-type layer;
a current spreading layer on the p-type layer; and
a contact layer between the current spreading layer and the p-type layer, the contact layer comprising a work function that is in a range from 6 electron volts (eV) to 10 eV.

12. The LED chip of claim 11, wherein the contact layer comprises at least one of molybdenum oxide, tungsten oxide, and vanadium oxide.

13. The LED chip of claim 11, wherein the contact layer comprises molybdenum oxide and the current spreading layer comprises indium tin oxide.

14. The LED chip of claim 11, further comprising:
a dielectric reflector layer on the current spreading layer;
a metal reflector layer on the dielectric reflector layer; and
a plurality of reflective layer interconnects that extend through the dielectric reflector layer to form a plurality of electrically conductive paths between the metal reflector layer and a plurality of discontinuous regions of the current spreading layer.

15. A light-emitting diode (LED) chip comprising:
an active LED structure comprising an n-type layer, a p-type layer, and an active layer between the n-type layer and the p-type layer;
a current spreading layer forming a plurality of discontinuous current spreading layer regions on the p-type layer; and
a contact layer between the current spreading layer and the p-type layer.

16. The LED chip of claim 15, wherein the contact layer forms a plurality of discontinuous contact layer regions.

17. The LED chip of claim 15, wherein the contact layer comprises a transition metal oxide.

18. The LED chip of claim 17, wherein the transition metal oxide comprises at least one of molybdenum oxide, tungsten oxide and vanadium oxide.

19. The LED chip of claim 15, wherein the contact layer comprises a work function in a range from 6 electron volts (eV) to 10 eV.

20. The LED chip of claim 15, further comprising:
a dielectric reflector layer on the current spreading layer;
a metal reflector layer on the dielectric reflector layer; and
a plurality of reflective layer interconnects that extend through the dielectric reflector layer to form a plurality of electrically conductive paths between the metal reflector layer and the plurality of discontinuous current spreading layer regions.
